(19) United States
(12) Patent Application Publication
(10) Pub. No.: US 2025/0155929 A1
(43) Pub. Date: May 15, 2025

(54) DISPLAY DEVICE

(71) Applicant: Lenovo (Singapore) Pte. Ltd., Singapore (SG)

(72) Inventors: Moriyuki Tsuchihashi, Kanagawa (JP); Kazuo Fujii, Kanagawa (JP)

(73) Assignee: Lenovo (Singapore) Pte. Ltd., Singapore (SG)

(21) Appl. No.: 18/823,139

(22) Filed: Sep. 3, 2024

(30) Foreign Application Priority Data
Nov. 15, 2023 (JP) 2023-194672

(51) Int. Cl. G06F 1/16

(52) U.S. Cl. CPC G06F 1/1652

(57) ABSTRACT

A display device includes: an OLED; a winder that winds the OLED from one end of the OLED; a constant force spring that applies a winding force of the OLED to the winder; strips each disposed on a corresponding edge of the OLED in a direction in which the OLED extends and is unwound, the strips being rollable around the winder together with the OLED and maintaining the OLED straight when the OLED is unwound; and a fixing mechanism configured to release the OLED when the OLED is pulled out in a direction along a winding direction of the OLED around the winder, and fix the OLED so that the OLED is not wound when the OLED is pulled out in a direction along an unwinding direction of the OLED around the winder.

### CROSS-REFERENCE TO RELATED APPLICATIONS

This application claims priority to Japanese Patent Application No. 2023-194672 filed on Nov. 15, 2023, the contents of which are hereby incorporated herein by reference in their entirety.

### TECHNICAL FIELD

The present invention relates to rollable display devices.

### BACKGROUND

Japanese Unexamined Patent Application Publication No. 2021-140162 discloses a rollable display device that can be wound up. This display device has a display unit that is wound and stored inside a stationary housing, and the display unit moves up and down by the action of a motor using a link mechanism.

The device in Japanese Unexamined Patent Application Publication No. 2021-140162 is in portrait orientation and appears to be adjustable in the vertical moving amount, but it is stationary and cannot be turned in landscape orientation. It is preferable that rollable display devices are made small enough for mobile use or to be supported by a simple stand. Furthermore, portable display devices are preferable if their display area is changeable and they can be used in both portrait and landscape orientations, allowing them to be used in a variety of different ways.

### SUMMARY

One or more embodiments of the present invention provide a display device that is usable in different ways.

A display device according to one or more embodiments of the present invention includes: an OLED; a winder that winds the OLED from one end of the OLED; a constant force spring that applies a winding force of the OLED to the winder; strips each disposed on a corresponding edge of the OLED in a direction in which the OLED extends and is unwound, the strips being rollable around the winder together with the OLED and maintaining the OLED straight when the OLED is unwound; and a fixing mechanism configured to release the OLED when the OLED is pulled out in a direction along a winding direction of the OLED around the winder, and fix the OLED so that the OLED is not wound when the OLED is pulled out in a direction along an unwinding direction of the OLED around the winder.

According to one or more embodiments of the present invention, the pulling-out of the OLED is adjustable to any amount, the OLED can be maintained in any orientation, and is useable in a variety of different ways.

### BRIEF DESCRIPTION OF THE DRAWINGS

FIG. 1 schematically illustrates a display device according to one or more embodiments of the present invention, and its external devices.

FIG. 2 is a schematic cross-sectional side view of a display device according to one or more embodiments.

FIG. 3 is a schematic cross-sectional front view of the display device according to one or more embodiments.

FIG. 4 is a schematic perspective view of a constant force spring.

FIG. 5 schematically illustrates a flexible display.

FIG. 6 is a schematic cross-sectional side view of the display device when the flexible display is pulled out therefrom.

FIG. 7 is a schematic cross-sectional side view of the display device when the flexible display is released from its fixed state.

FIG. 8 is a schematic cross-sectional side view of the display device when the flexible display is wound and stored.

FIG. 9 schematically illustrates a fixing mechanism according to a first modified example.

FIG. 10 schematically illustrates a fixing mechanism according to a second modified example.

FIGS. 11A-11D illustrate examples of the use of the display device according to one or more embodiments, with FIG. 11A illustrating the storage state, FIG. 11B illustrating the ready for use state, FIG. 11C illustrating the use state, and FIG. 11D illustrating another use state.

FIG. 12 is a schematic cross-sectional side view of the display device according to a second embodiment when the flexible display is released.

FIG. 13 is a schematic cross-sectional side view of the display device according to the second embodiment when the flexible display is pulled out a predetermined amount from the cover and fixed by a fixing mechanism.

FIGS. 14A-14B illustrate examples of the use of the display device according to the second embodiment, FIG. 14A illustrating an example of holding it with one hand and FIG. 14B illustrating an example of using a flexible tripod.

### DETAILED DESCRIPTION

The following describes a display device according to embodiments of the present invention in details, with reference to the drawings. The present invention is not limited to the following embodiments.

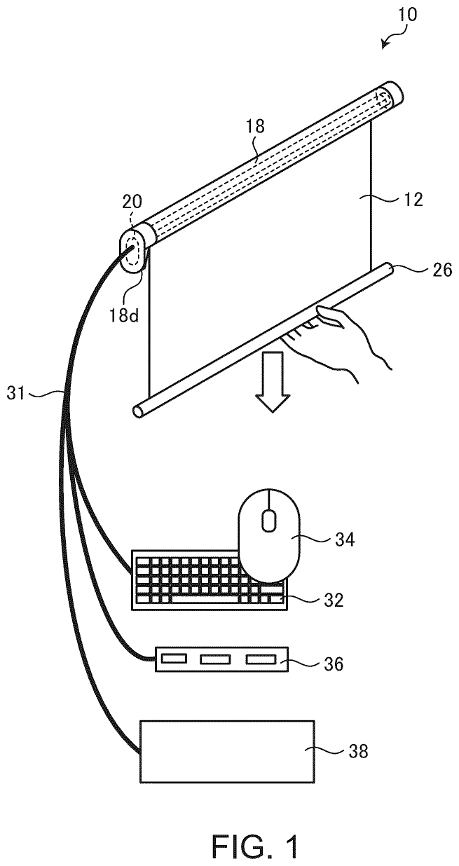

FIG. 1 schematically illustrates a display device 10 according to one or more embodiments of the present invention, and its external devices.

The display device 10 includes a display that is an organic light emitting display (OLED) 11. The OLED11 11 has features of its thinness and lightness in weight, low power consumption, and excellent contrast and responsiveness. The OLED 11 is flexible, meaning it is capable of being wound up, but its bending elasticity is relatively strong to have the property of returning to a flat shape in the absence of an external force. The following describes the display device 10: a display device 10A according to one or more embodiments; and a display device 10B according to one or more embodiments, in this order. The OLED 11 in these embodiments may have the dimensions of about 20 inches or 30 inches, for example.

First, the following describes the display device 10A according to one or more embodiments.

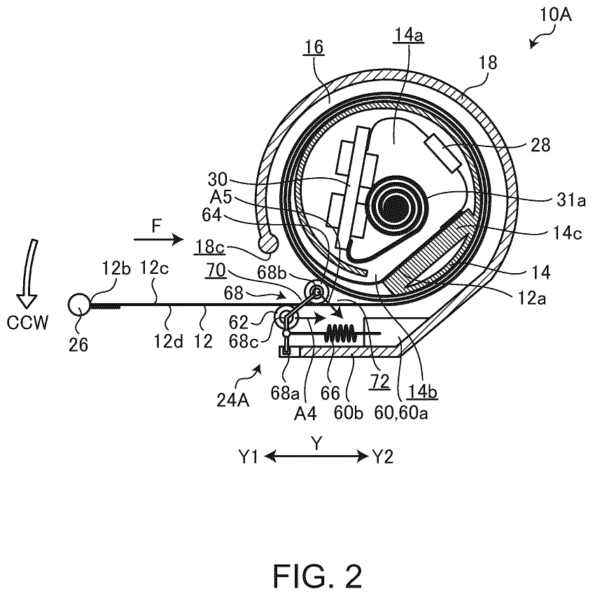

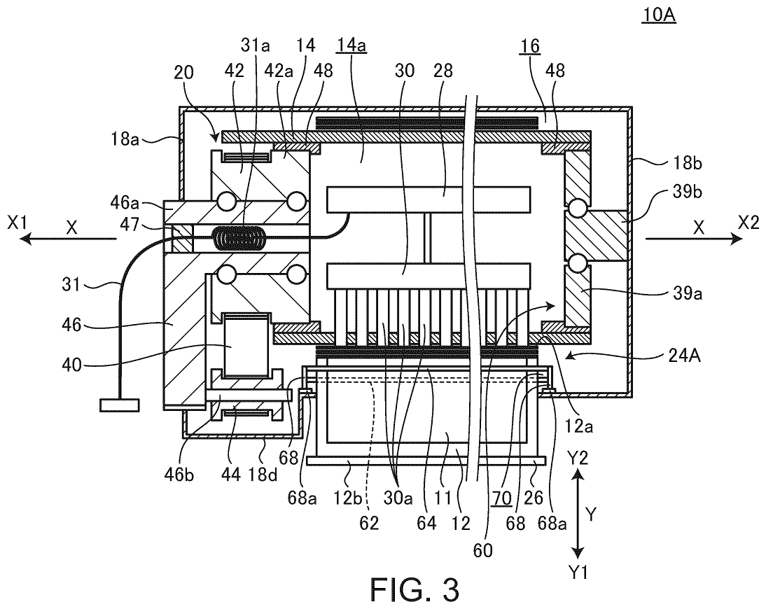

FIG. 2 is a schematic cross-sectional side view of the display device 10A. FIG. 3 is a schematic cross-sectional front view of the display device 10A. FIGS. 2 and 3 illustrate a flexible display 12 pulled out of a cover 18 by a predetermined amount and fixed by a fixing mechanism 24A.

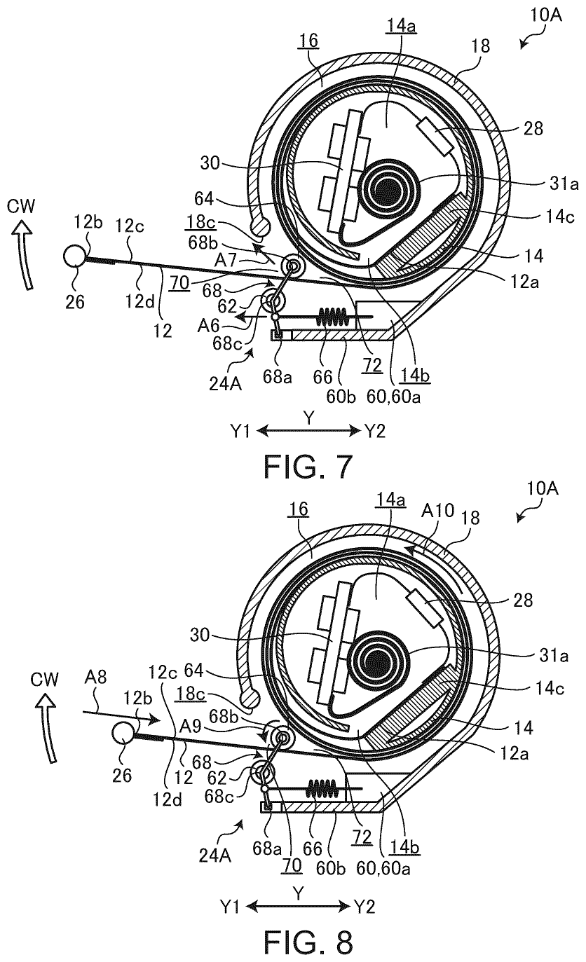

The display device 10A includes a flexible display 12, a cylinder (winder) 14, a cover 18, a constant force spring 20, a fixing mechanism 24A, a pull-out bar 26, a controller 28, and a display controller 30. The flexible display 12 has a surface, almost the entire of which the OLED 11 is provided, so that the flexible display 12 and the OLED 11 are substantially synonymous with each other in terms of winding and unwinding. The cylinder 14 is tubular and has a surface, around which the flexible display 12 is wound from one end 12a. In the description of the display device 10A, the extension direction of the cylinder 14 is defined as X direction. The cylinder 14 is tubular, and X direction corresponds to the axis direction of the tubular cylinder 14. The direction toward the constant force spring 20 is defined as X1 direction and the opposite direction is defined as X2 direction. The unwinding and winding direction of the flexible display 12 is defined as Y direction, where the direction toward the cylinder 14 is defined as Y1 direction, and the direction toward the pull-out bar 26 is defined as Y2 direction. In FIG. 2 and FIG. 7 described later, the direction along which the flexible display 12 is wound around the cylinder 14 is defined as CW direction, and the opposite direction is defined as CCW direction, to express the relative circumferential direction.

The cylinder 14 has a hollow 14a, in which the controller 28 and display controller 30 are placed. The controller 28 and the display controller 30 are elongated and extend in the X direction. The controller 28 and display controller 30 are connected by a control line.

The controller 28 corresponds to a motherboard in a typical personal computer. The controller 28 performs overall control of the display device 10A, and connects to the external devices via an interface cable 31. The interface cable 31 has a spiral portion 31a so that the rotation of the cylinder 14 is not transmitted to the outside.

The external devices include a keyboard 32, a mouse 34, a communication port 36, and an external battery 38. These external devices are connected as needed and may be disconnected when not needed. The controller 28 may be located outside the display device 10A. The battery may be located inside the display device 10A.

The display controller 30 controls the display of the OLED 11 and is a timing controller, for example. The cylinder 14 has a slit 14b (see FIG. 2), and one end 12a of the flexible display 12 is connected to the display controller 30 via a plurality of display control lines 30a through this slit 14b. From the viewpoint of horizontal display timing, the display controller 30 is desirably placed in the horizontal direction near the one end 12a of the flexible display 12, thus its layout in the X direction may be within the hollow 14a.

The cover 18 is a tubular housing that covers the entire display device 10A, and has both ends closed by lids 18a and 18b. The lids 18a and 18b may be provided with a power switch, a switch for adjusting the brightness of the OLED 11, and others. The cover 18 has a bulge 18d near the X1 end to accommodate the constant force spring 20. The cover 18 has a diameter somewhat larger than that of the cylinder 14 so as to have a winding space 16 for the flexible display 12 between itself and the cylinder 14. The diameter of the cover 18 is about 30 mm in one or more embodiments.

The cover 18 has a slit 18c (see FIG. 2), through which the flexible display 12 is unwound. The other end 12b of the flexible display 12 is outside the slit 18c. The other end 12b is provided with the pull-out bar 26 along its entire length. The pull-out bar 26 lets the user grip it when unwinding the flexible display 12, and is made of stainless steel, for example, and has a diameter that makes it easy to grip.

The X2 end of the cylinder 14 is supported by a bearing 39. The bearing 39 has an outer ring 39a, and an inner ring 39b. The inner ring 39b is fixed to the lid 18b. The outer ring 39a has the same diameter as a cylinder support 42a described later and is fixed to the inner wall of the cylinder 14 via a rubber ring 48.

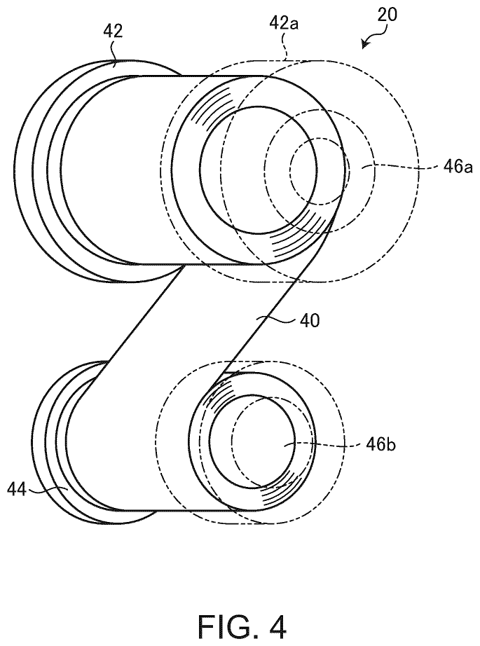

FIG. 4 is a schematic perspective view of the constant force spring 20. In FIG. 4, a part of the spring is illustrated by the dash-dot-dot imaginary lines. Referring to FIGS. 3 and 4, the following describes the constant force spring 20. The constant force spring 20 is placed at the X1 end of the cover 18. The constant force spring 20 includes an elastic band 40, a first pulley 42, and a second pulley 44. The first and second pulleys 42 and 44 are supported by first and second shafts 46a and 46b of a spring support 46. The spring support 46 is fixed to the lid 18a. A sensor for detecting a rotation angle may be placed between the first pulley 42 and the first shaft 46a so that the controller 28 understands the amount of the flexible display 12 that has been unwound.

A cylinder support 42a, which is located at the X2 end of the first pulley 42, is appropriately wide in the X direction, and is fixed to the inner wall of the cylinder 14 via a rubber ring 48. The first pulley 42 has a larger diameter than the second pulley 44. The first pulley 42 has a width in the X direction larger than that of the second pulley 44, and has a bearing structure between itself and the first shaft 46a. For instance, this bearing structure is of a double-row type, which allows the cylinder 14 to be stably supported for smooth rotation. The first shaft 46a has a hollow structure, through which the interface cable 31 passes. The interface cable 31 is secured in the hollow of the first shaft 46a with a grommet 47. The first pulley 42 is coaxial with the cover 18, and the second pulley 44 is in the bulge 18d. Although the constant force spring 20 is partially located in the bulge 18d, most of it fits inside the tube of the cover 18 and is small enough and lightweight enough.

The elastic band 40 is a metal spring member having bending elasticity such that it inherently spirals, which may be a spiral spring. The elastic band 40 hardly stretches in the pulling direction. The first pulley 42 is located at the X1 end of the cylinder 14, and the elastic band 40 is wound around the first pulley 42 in the opposite direction to the direction in which the elastic band 40 inherently spirals.

The second pulley 44 winds the elastic band 40 that is unwound from the first pulley 42 in the inherent spiral direction.

Such a constant force spring 20 always exerts a constant elastic force regardless of the amount of unwinding of the elastic band 40, thereby applying a rotational force to the first pulley 42. This rotational force gives a force F (see FIG. 2) that winds the flexible display 12 around the cylinder 14. The force F, which depends on the size of the flexible display 12, is about 800 gf, for example.

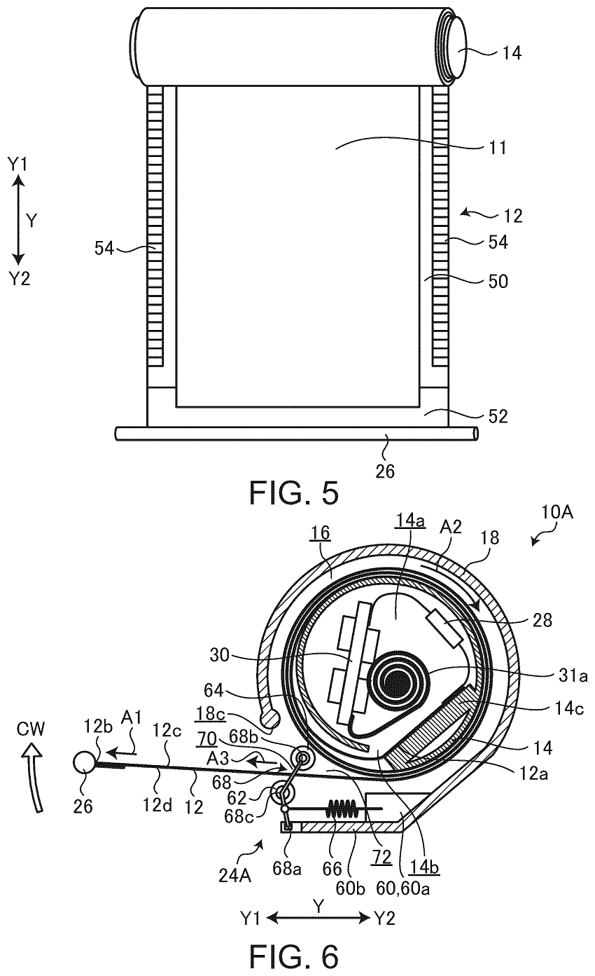

FIG. 5 schematically illustrates the flexible display 12. In addition to the OLED 11, the flexible display 12 includes a first sheet 50, a second sheet 52, and a pair of strips 54. The first sheet 50 is a base of the flexible display 12, and is made of a flexible, lightweight sheet that can be easily wound around the cylinder 14. The first sheet 50 has a surface, almost the entire which, except for the two ends in X direction, the OLED 11 is attached. The strips 54 are placed over almost the entire length in Y direction at both ends of the first sheet 50 where no OLED 11 is placed, and the strips 54 and the second sheet 52 are slightly spaced apart from each other. The strips 54 have an arc-shaped cross section similar to that of a metal measuring tape, called a convex, and can be wound together with the OLED 11 around the cylinder 14 and maintains the OLED 11 straight when unwinding. The strips 54 do not basically overlap with the OLED 11, but may overlap with the edge of the OLED 11 in a region other than the active area for display or when provided on the rear face of the first sheet 50.

The second sheet 52 is placed at the Y2 end of the flexible display 12 so as to extend the first sheet 50. The second sheet 52 is harder than the first sheet 50, and has a higher tensile strength especially in the Y direction. The Y2 end of the OLED 11 is on the second sheet 52 to be attached thereto. The second sheet end 52 is provided with the pull-out bar 26. The second sheet 52 has a short dimension in the Y-direction, meaning that the edge of the OLED 11 and the pull-out bar 26 are sufficiently close to each other. Note that the term “sheet” in this description has a broad definition and includes flexible materials such as cloth materials and mesh materials.

In this way, the OLED 11 is easy to be wound around the cylinder 14 because almost the entire surface is attached to the soft first sheet 50. When being unwound, both ends of the OLED 11 and flexible display 12 are maintained straight by the strips 54, so that they can be used in any direction. The OLED 11 and the flexible display 12 have their Y2 ends held by the pull-out bar 26, and their Y1 ends held by a guide bar 62 and a stop roller 64 (described later) at the slit 18c, which is the unwinding opening. This means that almost all of their four peripheries are held in a frame shape and stabilized. When the pull-out bar 26 is gripped and pulled, tension is generated in the flexible display 12 by the constant force spring 20, but the OLED 11 and the pull-out bar 26 are connected by the hard second sheet 52, so that they are free from deterioration such as stretching or breaking. When the OLED 11 is wound, a winding error may occur between the OLED 11 and the strips 54. This causes a slight misalignment in the winding direction after winding. If the strips 54 are attached to the hard second sheet 52, this winding error cannot be corrected, and a force causing a torsional distortion will be applied to the OLED 11. In contrast, the strips 54 and second sheet 52 in one or more embodiments are separated from each other, so that such a winding error does not occur.

As illustrated in FIGS. 2 and 3, the fixing mechanism 24A is placed on a base 60 formed at one edge of the slit 18c of the cover 18, and includes a guide bar 62, a stop roller 64, a push spring 66, and a pair of support angles 68. The base 60 has a block 60a fixed to a tubular portion of the cover 18, and a protruding wall 60b protruding in Y1 direction from the block 60a.

The stop roller 64 traverses the entire width of the flexible display 12 in the X direction along the inner face 12c of the flexible display 12 that is wound around the cylinder 14. The inner face 12c is the face, on which the OLED 11 is attached. The guide bar 62 traverses the entire width of the flexible display 12 in the X direction along the outer face 12d of the flexible display 12 that is wound around the cylinder 14.

The support angles 68 have an obtuse L-shape and support both ends of the guide bar 62 and the stop roller 64. The support angles 68 each have: a support portion 68a at one end, which is supported tiltably relative to the tip of the protruding wall 60b; the other end 68b that rotatably supports the stop roller 64; and a bend portion 68c that non-rotatably supports the guide bar 62. The stop roller 64 and the guide bar 62 are adjacent to and parallel to each other, and the flexible display 12 passes through a gap 70 between them. The gap 70 is appropriately narrow so that the pull-out bar 26 does not slip out in the Y1 direction. The push spring 66 has one end engaged with the block 60a and the other end engaged with an intermediate portion between the support portion 68a and the bend portion 68c, and elastically biases the support angle 68 in the Y2 direction. That is, the guide bar 62 and the stop roller 64 are elastically biased together in the Y2 direction via the support angles 68. The support angles 68 are displaceable in the Y2 direction until they hit a predetermined stopper (see FIG. 6), where the amount of displacement is small. The biasing force of the push spring 66 is small. The guide bar 62 and stop roller 64 have surfaces made of silicone rubber (rubber material) to prevent slipping against the flexible display 12.

FIG. 6 is a schematic cross-sectional side view of the display device 10A when the flexible display 12 is unwound therefrom. When the flexible display 12 is unwound through the slit 18c of the cover 18, the user grasps the pull-out bar 26 and pulls it while slightly moving it to the CW side (arrows A1, A2). While the flexible display 12 receives a force in the winding direction by the constant force spring 20, the user is able to pull it out with a constant force regardless of the pulling-out amount.

At this time, the support angles 68 of the fixing mechanism 24A are pushed out by the push spring 66 (arrow A3) and are displaced in the Y1 direction to a position where they abut against the stopper. The flexible display 12 can be pulled out through the gap 70 without touching either the stop roller 64 or the guide bar 62.

When the OLED 11 is lifted upward and pulled out, the inner face 12c abuts against the stop roller 64. In this case, the OLED 11 can be pulled out without almost no resistance because the stop roller 64 is freely rotatable, and the OLED 11 on the inner face 12c is not damaged. The frictional force is small when the outer face 12d of the flexible display 12 abuts against the guide bar 62, and does not impact on the pulling out of the flexible display 12.

When the user pulls out the flexible display 12 to a certain length and releases the pull-out bar 26, the device has the state as in FIG. 2, where the flexible display 12 is fixed by the fixing mechanism 24A. That is, the flexible display 12 is momentarily wound in the Y2 direction by the constant force spring 20, so that it is displaced slightly in the CCW direction, and the outer face 12d immediately comes into contact with the guide bar 62 because the gap 70 is narrow. Then, the support angles 68 are displaced in the Y2 direction together with the flexible display 12 due to the frictional force between the guide bar 62 and the outer face 12d (arrow A4). The biasing force of the push spring 66 is small and does not interfere with the displacement of the support angles 68.

At the slit 18c, the flexible display 12 is tangent to the multilayered winding portion around the cylinder 14 (when the entire length of the flexible display 12 is unwound, the cylinder 14 itself), and defines an acute angle gap 72. As the support angles 68 tilt in the Y1 direction, the stop roller 64 enters the gap 72, and acts like a wedge to stop the flexible display 12 from being pulled in and fix it in place (arrow A5). The guide bar 62 continues to be biased in the Y1 direction by friction with the outer face 12d, so that the position of the support angles 68 is maintained.

Practically, it takes only a moment from when the user releases the pull-out bar 26 until the display is fixed by the stop roller 64, and the amount of flexible display 12 wound up is extremely small, so that the flexible display 12 can be fixed at any position without causing the user any discomfort. The fixing mechanism 24A fixes the flexible display 12 against the constant force spring 20 so that it cannot be at least wound up, and has a suitable fixing force to maintain the state of FIG. 2 also in the unwinding direction.

The surface of the stop roller 64 includes silicone rubber, which prevents the flexible display 12 from being wound up while causing slippage. The OLED 11 has a relatively strong bending elasticity. Thus, the OLED 11 is securely supported by the stop roller 64, and the flexible display 12 is fixed. The stop roller 64 acts uniformly over the entire length of the OLED 11 in the X direction. The stop roller 64 abuts against not only the OLED 11 but also the strips 54 which are maintained straight, thereby enabling the flexible display 12 to be fixed more reliably.

FIG. 7 is a schematic cross-sectional side view of the display device 10 when the flexible display 12 is released from its fixed state. FIG. 8 is a schematic cross-sectional side view of the display device 10 when the flexible display 12 is wound and stored.

To release the flexible display 12 from the fixed state, the user may grasp the pull-out bar 26 and move it slightly in the CW direction as illustrated in FIG. 7. Then, the stop roller 64 rotates and the support angles 68 are balanced while being slightly pushed in the Y1 direction by the push spring 66 with a weak force, without moving in either the Y1 or Y2 direction. Specifically, the spring force of the push spring 66 may be smaller than the friction force between the silicone rubber surface of the stop bar 62 and the OLED 11 in FIG. 2, and have a strength sufficient to return the support angles 68 in the Y1 direction when the support angles 68 are free.

The guide bar 62 is released away from the flexible display 12, and is elastically biased by the push spring 66 in the Y1 direction and displaced (arrow A6). The stop roller 64 comes out of the gap 72 (arrow A7), and the flexible display 12 is released from its fixed state. After this, the flexible display 12 can be pulled out further as illustrated in FIG. 6. When winding and storing the flexible display 12, the force to pull the pull-out bar 26 is loosened while keeping it in the CW direction as illustrated in FIG. 8 (arrow A8). Then, the stop roller 64 comes into contact with the inner face 12c and rotates (arrow A9) due to the winding force of the constant force spring 20, and the flexible display 12 is wound (arrow A10).

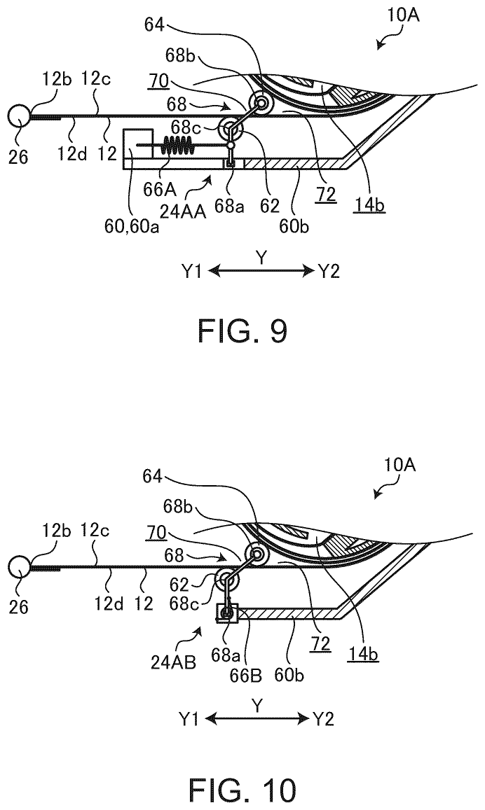

FIG. 9 schematically illustrates a fixing mechanism 24AA according to a first modified example. FIG. 10 schematically illustrates a fixing mechanism 24AB according to a second modified example. The fixing mechanism 24AA is configured so that the protruding wall 60b extends further in the Y1 direction beyond the support portion 68a, and has a block 60a at its tip. A pull spring 66A is placed between the block 60a and the support angles 68 so that the support angles 68 are elastically biased in the Y1 direction. The fixing mechanism 24AB includes a torsion spring 66B around the support portion 68a to elastically bias the support angles 68 in the Y1 direction. In one or more embodiments, the support angles 68 have an obtuse L-shape, the guide bar 62 and the stop roller 64 are positioned appropriately, and the portion connecting the bend portion 68c to the support portion 68a is substantially perpendicular to the Y direction, so that the support angles 68 are tiltable in a balanced way between in the Y1 and Y2 directions. Note that the support angles 68 may be a right angled L-shape, straight line shape, and others, depending on the layout requirements.

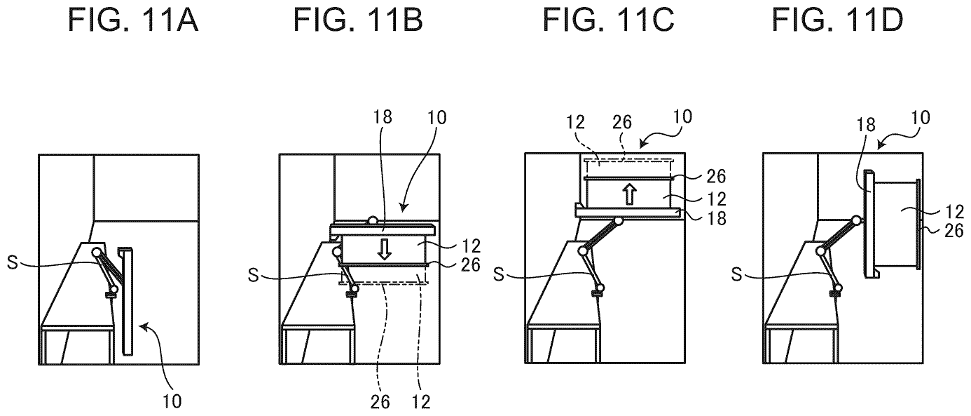

FIGS. 11A-11D illustrate examples of the use of the display device according to one or more embodiments, with FIG. 11A illustrating the storage state, FIG. 11B illustrating the ready for use state, FIG. 11C illustrating the use state, and FIG. 11D illustrating another use state.

The display device 10A is small and lightweight, so it is attachable to a lighting desk stand S as illustrated in FIGS. 11A-11D and movable to any desired position for use. As illustrated in FIG. 11A, the display device 10A may be stored vertically so as to reduce the space it occupies. When in use, the display device 10A may be set at any position and height.

The orientation of the display device 10A during use is not limited. As illustrated in FIG. 11B, the flexible display 12 may be pulled downward, as illustrated in FIG. 11C, the flexible display 12 may be pulled upward, or as illustrated in FIG. 11D, the flexible display 12 may be pulled out sideways. Any pulling amount of the flexible display 12 may be set, as described above. The display device 10A may be stored horizontally.

According to the above-described display device 10A, when the unwinding direction of the OLED 11 and the flexible display 12 is in the CW direction relative to the slit 18c (see FIG. 6), the OLED 11 and the flexible display 12 are released; and when the unwinding direction is in the CCW direction relative to the slit 18c, the OLED 11 and the flexible display 12 are fixed so that they cannot be wound up. The unwound flexible display 12 is held in a frame shape by the pull-out bar 26, guide bar 62, stop roller 64, and two strips 54 to be stable in any orientation, so the flexible display 12 can be used in both portrait and landscape orientations.

The display device 10A has the OLED 11 and the constant force spring 20 housed inside the tubular cover 18, and is small, lightweight, inexpensive, and highly portable. The display device 10A does not require a link mechanism as in Japanese Unexamined Patent Application Publication No. 2021-140162, and does not require a power source to drive the link mechanism, and thus does not require a motor. The display device 10A is rollable, compact and lightweight, and can be used for mobile applications or be supported with a simple stand.

Although the OLED 11 has a property to return to a flat shape, it is constantly biased by the constant force spring 20, so that it is maintained in an appropriate wound state around the cylinder 14 and does not expand radially outward within the space 16 to come into contact with the inner wall of the cover 18. Therefore, it does not slide against the cover 18 and is not damaged or subjected to unnecessary frictional forces. The display area of the display device 10A is changeable, so that the aspect ratio can be set to 1:3, 3:4, 4:3, 16:9, 21:9, and others. In this way, the display device 10A can be used in different ways. This allows the display device to change the size depending on the purpose, such as on the train, as the main display on the desk, or as a large sub-display.

Next, the following describes the display device 10B according to one or more embodiments. Like numbers indicate like components in the display device 10A as stated above, and their detailed descriptions are omitted.

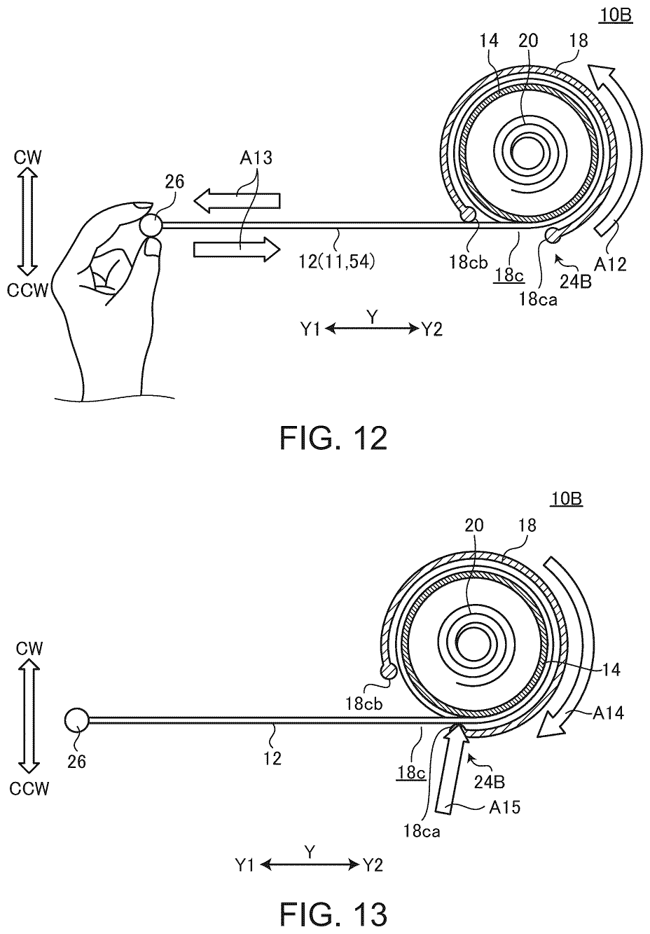

FIG. 12 is a schematic cross-sectional side view of the display device 10B when the flexible display 12 is released. FIG. 13 is a schematic cross-sectional side view of the display device 10B when the flexible display 12 is pulled out a predetermined amount from the cover 18 and fixed by a fixing mechanism 24B.

The display device 10B includes the fixing mechanism 24B in place of the fixing mechanism 24A to fix the flexible display 12. In the display device 10B, the slit 18c has one end 18ca on the unwinding side (CCW side) of the flexible display 12 relative to cylinder 14, and the other end 18cb on the winding side (CW side). Of these, the end 18ca acts as the fixing mechanism 24B. For instance, these ends 18ca and 18cb have a circular cross section and are slightly thicker.

As illustrated in FIG. 12, when the user grips the pull-out bar 26 and turns the cover 18 in the CCW direction relative to the cylinder 14 (arrow A12), the unwinding direction of the flexible display 12 becomes closer in the CW direction relative to the slit 18c. Then, the flexible display 12 is separated from the end 18ca on the CCW side at the slit 18c, and can be unwound and wound (arrow A13).

As illustrated in FIG. 13, when the user releases the pull-out bar 26, the flexible display 12 is displaced to the CCW side at the slit 18c due to the force of the OLED 11 and the strips 54 returning to a flat shape. In other words, the cover 18 rotates in the CW direction relative to the flexible display 12 (arrow A14). The flexible display 12 is then pressed by the end 18ca at the slit 18c (arrow A15). The flexible display 12 is fixed at the slit 18c because it is pressed against the multilayered winding portion around the cylinder 14 (when the entire length of the flexible display 12 is unwound, the cylinder 14 itself). Such a display device 10B has a simple structure and can be made compact and lightweight, and can be used as a tablet terminal, for example. Like the display device 10A, the flexible display 12 of the display device 10B can be pulled out any length and then used in any orientation.

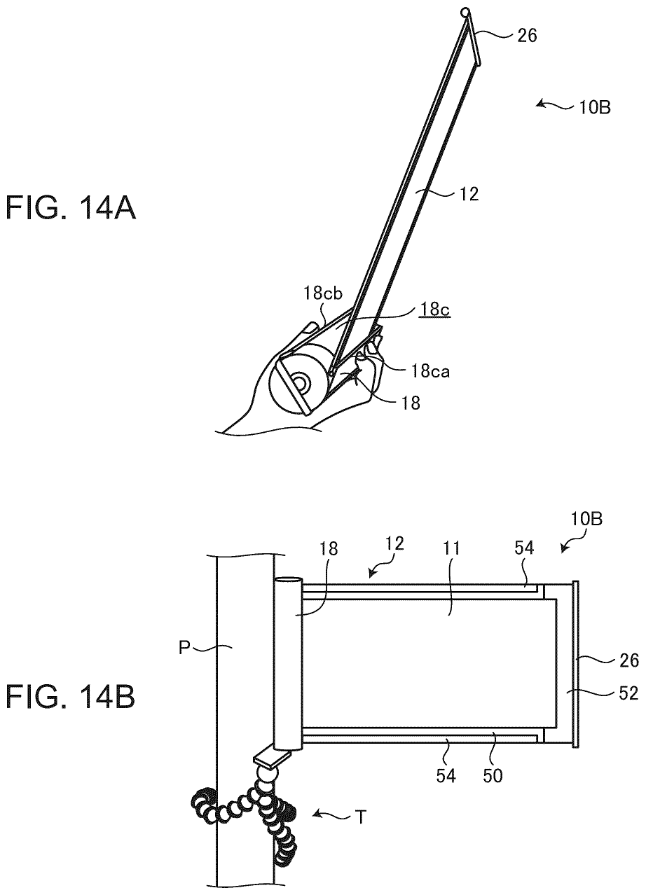

As illustrated in FIG. 14A, the compact and lightweight display device 10B can be used while being held in one hand, and the orientation of the flexible display 12 is maintained even if the flexible display is released from the hand. As illustrated in FIG. 14B, the compact and lightweight display device 10B can be used by connecting a small flexible tripod T to the end of the cover 18 and mounting it on a pillar P. For some positions of the center of gravity, the display device can also be used on a tabletop with the flexible tripod T. Although the usage forms of the display device 10A and display device 10B have been explained separately in FIGS. 11A-11D and 14A-14B, the display device 10A may be used as in FIGS. 14A-14B and the display device 10B may be used as in FIGS. 11A-11D. The display devices 10A and 10B are small and lightweight, so they can be used as a wall-mounted type or a magnetically attached type.

The present invention is not limited to the above-described embodiments, and can be modified freely without deviating from the scope of the present invention.

### DESCRIPTION OF SYMBOLS

10, 10A, 10B display device
11 OLED
12 flexible display
14 cylinder
14b slit
16 winding space
18 cover
18c slit
20 constant force spring
24A, 24AA, 24AB, 24B fixing mechanism
26 pull-out bar
50 first sheet
52 second sheet
54 strip
62 guide bar
64 stop roller
66 push spring
68 support angle
70 gap
72 gap

What is claimed is:

1. A display device comprising:
an OLED;
a winder that winds the OLED from one end of the OLED;
a constant force spring that applies a winding force of the OLED to the winder;
strips each disposed on a corresponding edge of the OLED in a direction in which the OLED extends and is unwound, the strips being rollable around the winder together with the OLED and maintaining the OLED straight when the OLED is unwound; and
a fixing mechanism configured to release the OLED when the OLED is pulled out in a direction along a winding direction of the OLED around the winder, and fix the OLED so that the OLED is not wound when the OLED is pulled out in a direction along an unwinding direction of the OLED around the winder.

2. The display device according to claim 1, wherein
the fixing mechanism includes:
a guide bar that traverses an entire width of the OLED along an outer face of the OLED that is wound around the winder; and
a stop roller that traverses the entire width of the OLED along an inner face of the OLED that is wound around the winder,
wherein
the stop roller and the guide bar are adjacent to and parallel to each other, and are elastically biased together in the unwinding direction of the OLED.

3. The display device according to claim 2, wherein
the stop roller has a surface, the surface including a rubber material.

4. The display device according to claim 1, further comprising a cover that keeps a winding space for the OLED between the winder and the cover, the cover having a slit, through which the OLED is unwound, wherein
the fixing mechanism includes an end of the slit in the unwinding direction of the OLED around the winder.

5. The display device according to claim 1, wherein
the OLED is attached to a first sheet,
a second sheet is disposed at an unwinding end of the OLED to extend the first sheet, the second sheet being harder than the first sheet, and
the second sheet comes with a pull-out bar to let a user unwind the OLED.
